(19) United States
(12) Patent Application Publication
(10) Pub. No.: US 2026/0292971 A1
(43) Pub. Date: Sep. 24, 2026

(54) CIRCUIT BOARD DEVICE

(71) Applicants: GLOBAL UNICHIP CORPORATION, HSINCHU CITY (TW); TAIWAN SEMICONDUCTOR MANUFACTURING COMPANY, LTD., Hsinchu (TW)

(72) Inventors: Huan-Yi LIAO, HSINCHU CITY (TW); Sheng-Fan YANG, HSINCHU CITY (TW); Hung-Tao LU, HSINCHU CITY (TW)

(21) Appl. No.: 19/199,407

(22) Filed: May 6, 2025

(30) Foreign Application Priority Data
Mar. 24, 2025 (TW) 114111042

(51) Int. Cl. H05K 1/02

(52) U.S. Cl. CPC H05K 1/0245; H05K 2201/09545; H05K 2201/09609; H05K 2201/09618; H05K 2201/09636; H05K 2201/09845

(57) ABSTRACT

A circuit board device includes a multilayer board structure and differential pair routings. The multilayer board structure includes two plate layers and a core layer between the plate layers. Each differential pair routing includes a first PTH having a first conductive hole and a first laser through hole electrically connected to the first conductive hole, and a second PTH having a second conductive hole and a second laser through hole electrically connected to the second conductive hole. The second conductive hole and the first conductive hole are parallel to each other to form a first spacing. The first laser through hole and the second laser through hole are between the imaginary extension lines of the first conductive hole and the second conductive hole, and a second spacing defined between the first laser through hole and the second laser through hole is smaller than the first spacing.

### RELATED APPLICATIONS

This application claims priority to Taiwanese Application Serial Number 114111042 filed Mar. 24, 2025, which is herein incorporated by reference.

### BACKGROUND

### Field of Invention

The present disclosure relates to a circuit board device. More particularly, the present disclosure relates to a circuit board device capable of providing differential signal transmission.

### Description of Related Art

As electronic products are getting more and more versatile, system design encounters increasing challenges in balancing performance, size, speed and cost. The present package designs of integrated circuits (IC) must not only accommodate high-density layouts, but also meet stringent requirements for signal integrity (SI) and power integrity (PI) during high-speed data transmission.

However, due to the increasingly compact arrangement of components on the circuit board of electronic products, high-speed and high-frequency signals within the circuit board are affected by crosstalk phenomena during transmission, such as far-end crosstalk, thereby impacting signal integrity.

As seen above, the technology above is still accompanied with inconveniences and shortcomings, and needed to be further improved. Therefore, how to effectively address these inconveniences and shortcomings has become one of the key research and development topics at present, as well as an urgent goal for improvement in the related field.

### SUMMARY

One aspect of the present disclosure is to provide a circuit board device for solving the difficulties mentioned above in the prior art.

In one embodiment of the present disclosure, a circuit board device includes a multilayer board structure and differential pair routings. The multilayer board structure includes a core layer, at least one first plate layer and a plurality of second plate layers stacked one another, and the core layer that is sandwiched between the first plate layer and the second plate layers. Each of the differential pair routings includes a first plating through hole (first PTH) and a second plating through hole (second PTH). The first PTH includes a first conductive hole and a first laser through hole. The first conductive hole is located within the core layer, and the first laser through hole is sequentially passed through the second plate layers and electrically connected to the first conductive hole. The second PTH includes a second conductive hole and a second laser through hole. The second conductive hole is located within the core layer, and the second laser through hole is sequentially passed through the second plate layers and electrically connected to the second conductive hole. When viewed in cross-sectional view, a pattern of the first PTH and a pattern of the second PTH are mirror-symmetrical to each other, the second conductive hole is parallel to the first conductive hole, and a first spacing is formed between the second conductive hole and the first conductive hole, the first laser through hole and the second laser through hole are completely between an imaginary extension line of the first conductive hole and an imaginary extension line of the second conductive hole, and a second spacing defined between the first laser through hole and the second laser through hole is smaller than the first spacing.

In one embodiment of the present disclosure, a circuit board device includes a multilayer board structure and differential pair routings. The multilayer board structure includes a solder-ball surface, a core layer and a plurality of plate layers stacked one another, and the plate layers sandwiched between the solder-ball surface and the core layer. The differential pair routings are spaced distributed within the multilayer board structure. Each of the differential pair routings includes a P-type PTH and a N-type PTH which are mirror-symmetrical. The P-type PTH includes a first conductive hole and a first laser through hole, the first conductive hole is located within the core layer, and the first laser through hole is sequentially passed through the plate layers and electrically connected to the first conductive hole, and the N-type PTH includes a second conductive hole and a second laser through hole. The second conductive hole is located within the core layer, and the second laser through hole is sequentially passed through the plate layers and electrically connected to the second conductive hole. When viewed in cross-sectional view, the second conductive hole is parallel to the first conductive hole, and a first spacing is formed between the second conductive hole and the first conductive hole, the first laser through hole and the second laser through hole are completely between an imaginary extension line of the first conductive hole and an imaginary extension line of the second conductive hole, and a second spacing defined between the first laser through hole and the second laser through hole is smaller than the first spacing.

Thus, through the construction of the embodiments above, even if the components on the circuit board device are gradually arranged closely in position, the circuit board device of the present disclosure can still reduce the crosstalk effect during signal transmission and improve signal integrity.

The above description is merely used for illustrating the problems to be resolved, the technical methods for resolving the problems and their efficacies, etc. The specific details of the present disclosure will be explained in the embodiments below and related drawings.

### BRIEF DESCRIPTION OF THE DRAWINGS

The disclosure can be more fully understood by reading the following detailed description of the embodiment, with reference made to the accompanying drawings as follows.

FIG. 1 is a partial top view of a circuit board device according to one embodiment of the present disclosure.

FIG. 2 is a cross-sectional view of the circuit board device of FIG. 1 taken along a line A-A.

FIG. 3 is a side view of one of differential pair routings according to one embodiment of the present disclosure.

FIG. 4 is a side view of one of differential pair routings according to one embodiment of the present disclosure.

FIG. 5 is a cross-sectional view of the circuit board device of FIG. 1 taken along a line B-B.

### DETAILED DESCRIPTION

Reference will now be made in detail to the present embodiments of the present disclosure, examples of which are illustrated in the accompanying drawings. Wherever possible, the same reference numbers are used in the drawings and the description to refer to the same or like parts. According to the embodiments, it will be apparent to those skilled in the art that various modifications and variations can be made to the structure of the present disclosure without departing from the scope or spirit of the present disclosure.

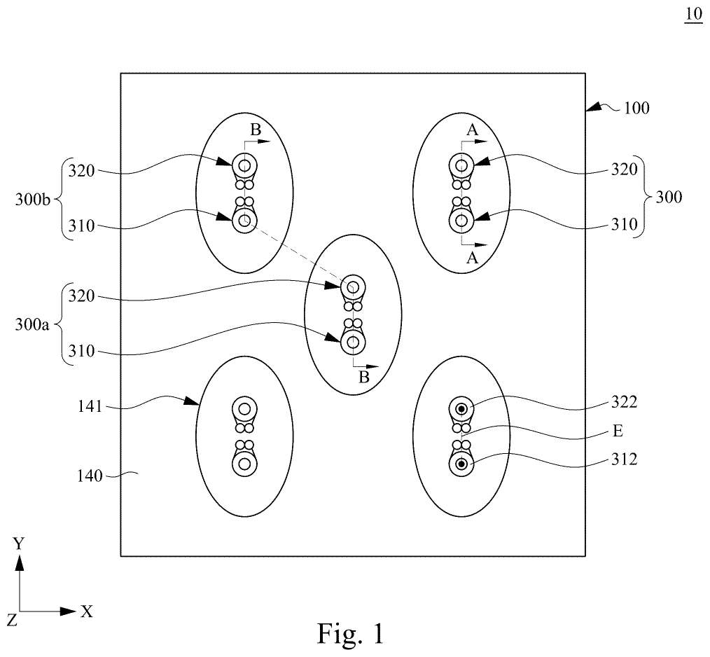

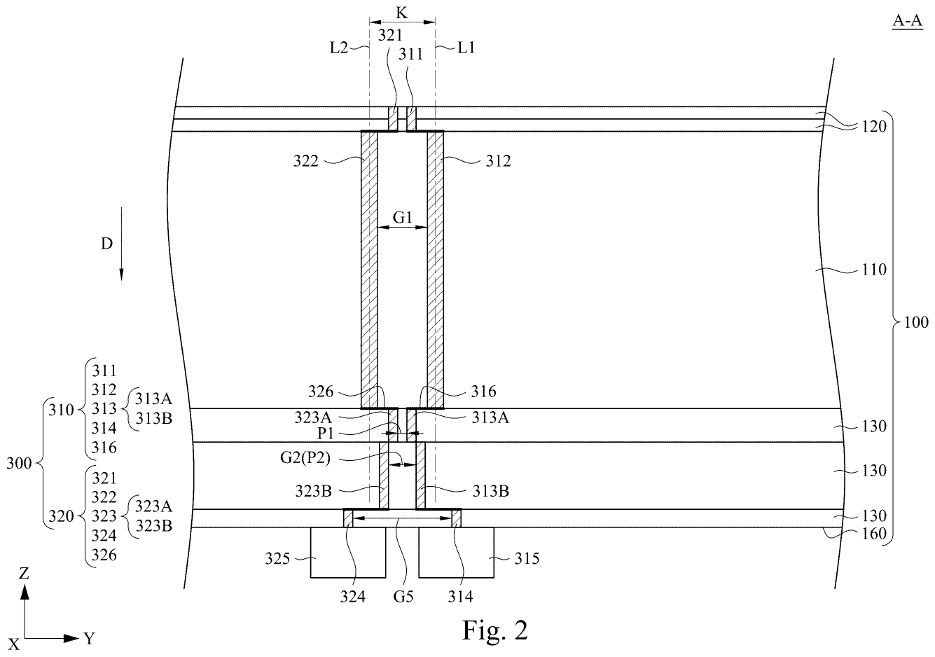

Reference is now made to FIG. 1 to FIG. 2 in which FIG. 1 is a partial top view of a circuit board device 10 according to one embodiment of the present disclosure, and FIG. 2 is a cross-sectional view of the circuit board device 10 of FIG. 1 taken along a line A-A. The circuit board device 10 includes a multilayer board structure 100 and a plurality of differential pair routings 300. The multilayer board structure 100 includes a core layer 110, a plurality of first plate layers 120 stacked one another in a vertical direction (e.g., Z-axle), and a plurality of second plate layers 130 stacked one another in the vertical direction (e.g., Z-axle). The configuration surfaces of the first plate layers 120 and the second plate layers 130 are made of insulating material, and pattern circuits are distributed and printed on the insulating material. The core layer 110 is sandwiched between the first plate layers 120 and the second plate layers 130. In addition, the multilayer board structure 100 further includes a solder-ball surface 160 (e.g., BGA) and a contact surface (e.g., bump, not shown in figures) opposite to each other. The first plate layers 120 are located between the core layer 110 and the contact surface, and the second plate layer 130 is located between the core layer 110 and the solder-ball surface 160. The contact surface is used to connect to a chip set (not shown) through electrical contacts (not shown), and the solder-ball surface 160 is used to place solder balls that can be soldered to a circuit load board (not shown).

Refer to FIG. 1 and FIG. 2 again, these differential pair routings 300 are spaced distributed along the X-Y axis direction on the multilayer board structure 100. Specifically, structurally, each of the differential pair routings 300 includes a pair (i.e., two) of differential signal routings, that is, two differential via holes, a first plating through hole (first PTH) and a second plating through hole (second PTH), representing a P-type PTH and a N-type PTH, respectively. These differential pair routings 300 are used to provide differential signal transmission. In the above description, the layout methods of the two signal vias of the differential pair routings 300 are substantially the same or similar. That is to say, the lengths of the two signal through vias are substantially similar, and the routing directions are substantially mirror-symmetrical to each other.

For example, the first PTH 310 includes a first conductive hole 312, a first laser through hole 313 and a first solder-ball via 314. The first conductive hole 312 is located within the core layer 110. The first laser through hole 313 is sequentially passed through the second plate layers 130 and electrically connected to the first conductive hole 312 and the first solder-ball via 314. The first solder-ball via 314 is located within the second plate layers 130 for connecting to a first solder ball 315. The second PTH 320 includes a second conductive hole 322, a second laser through hole 323 and a second solder-ball via 324. The second conductive hole 322 is located within the core layer 110. The second laser through hole 323 is sequentially passed through the second plate layers 130 and electrically connected to the second conductive hole 322 and the second solder-ball via 324. The second solder-ball via 324 is located within the second plate layers 130 for connecting to a second solder ball 325.

Additionally, the first PTH 310 further includes a first upper guide hole 311. The first upper guide hole 311 is sequentially passed through the first plate layers 120 and electrically connected to the first conductive hole 312. More specifically, any two adjacent ones of the first upper guide hole 311, the first conductive hole 312, the first laser through hole 313 and the first solder-ball via 314 are respectively provided with an interface layer (not shown in figures) and connected to each other through a first planar routing 316 on the corresponding interface layer. Any two adjacent ones of the second upper guide hole 321, the second conductive hole 322, the second laser through hole 323 and the second solder-ball via 324 are respectively provided with an interface layer (not shown in figures) and connected to each other through a second planar routing 326 on the corresponding interface layer. The first conductive hole 312 and the second conductive hole 322 may be collectively referred to as a via pair, and the first laser through hole 313 and the second laser through hole 323 may be collectively referred to as a laser via pair.

As shown in FIG. 2, a pattern of the first PTH 310 and a pattern of the second PTH 320 are mirror-symmetrical to each other. The first conductive hole 312 and the second conductive hole 322 are parallel to each other, that is, the first conductive hole 312 and the second conductive hole 322 are presented as linear columns. The first laser through hole 313 and the second laser through hole 323 are retracted inward from an imaginary extension line L1 of the first conductive hole 312 and an imaginary extension line L2 of the second conductive hole 322, respectively. That is, the pattern of the first laser through hole 313 and the pattern of the second laser through hole 323 are stepped or straight, and are symmetrically arranged and approach each other, so that the first laser through hole 313 and the second laser through hole 323 are completely located between the imaginary extension line L1 of the first conductive hole 312 and the imaginary extension line L2 of the second conductive hole 322.

As shown in FIG. 1, as viewed in the top view, a connection line between hole-axes of the first conductive hole 312 and the second conductive hole 322 has an extension direction (e.g., Y axle), and as shown in FIG. 2, the first laser through hole 313 and the second laser through hole 323 respectively extend toward each other according to the extending direction E (see Y axis, FIG. 2).

It is noted, FIG. 1 can be shown the differential pair routings 300 by seeing through a part of the first plate layers 120 of the circuit board device 10, so the part of the first plate layers 120 can be omitted in FIG. 2.

Thus, as shown in FIG. 2, a first spacing G1 is formed between the first conductive hole 312 and the second conductive hole 322, and a second spacing G2 is defined between the first laser through hole 313 and the second laser through hole 323, and the second spacing G2 is smaller than the first spacing G1. A first gap G5 is defined between the first solder-ball via 314 and the second solder-ball via 324, and the first gap G5 is greater than the first spacing G1. Specifically, the first spacing G1 refers to a minimum linear distance between the first conductive hole 312 and the second conductive hole 322 along the Y-axis. The first gap G5 refers to a minimum linear distance between the first solder-ball via 314 and the second solder-ball via 324 along the Y-axis.

Thus, since the first laser through hole 313 and the second laser through hole 323 of each of the differential pair routings 300 are retracted inward from the first conductive hole 312 and the second conductive hole 322, respectively, even if the components on the circuit board device 10 are gradually arranged closely in position, the differential signals transmitted on the adjacent differential pair routings 300 will not be seriously affected by crosstalk, thereby improving signal integrity.

More specifically, as shown in FIG. 2, the first laser through hole 313 and the second laser through hole 323 gradually apart away from each other in a direction D from the core layer 110 towards the second plate layers 130of the multilayer board structure 100, but do not exceed out of a scope between the imaginary extension line L1 of the first conductive hole 312 and the imaginary extension line L2 of the second conductive hole 322. More specifically, the first laser through hole 313 includes a first segment 313A and a second segment 313B. The first segment 313A is connected to the second segment 313B and the first conductive hole 312, and the second segment 313B is connected to the first solder-ball via 314. The second laser through hole 323 includes a third segment 323A and a fourth segment 323B. The third segment 323A is connected to the fourth segment 323B and the second conductive hole 322. The fourth segment 323B is connected to the second solder-ball via 324. A first via hole spacing P1 is defined between the first segment 313A and the third segment 323A, and a second via hole spacing P2 is defined between the second segment 313B and the fourth segment 323B. The second via hole spacing P2 is greater than the first via hole spacing P1, and is the same as the second spacing G2. More specifically, the second spacing G2 is the minimum linear distance between the second segment 313B of the first laser through hole 313 and the fourth segment 323B of the second laser through hole 323 along the Y axis.

It is noted, each of the differential pair routings 300 only has a laser via between the first conductive hole 312 and the second conductive hole 322. In other words, a configuration area K is defined between the imaginary extension line L1 of the first conductive hole 312 and the imaginary extension line L2 of the second conductive hole 322. The first PTH 310 and the second PTH 320 do not have any laser through hole outside the configuration area K.

Refer to FIG. 1 and FIG. 2 again, the multilayer board structure 100 further includes a ground layer 140 and a plurality of closed openings 141 spaced formed on the ground layer. The ground layer 140 is disposed in a plane within the multilayer board structure 100. Each of the closed openings 141 surrounds and exposes a corresponding one of the differential pair routings 300. For example, the ground layer 140 is a copper foil grounding layer, which extends along the X-Y axis direction and may be located within any one of the first plate layers 120 and the second plate layers 130.

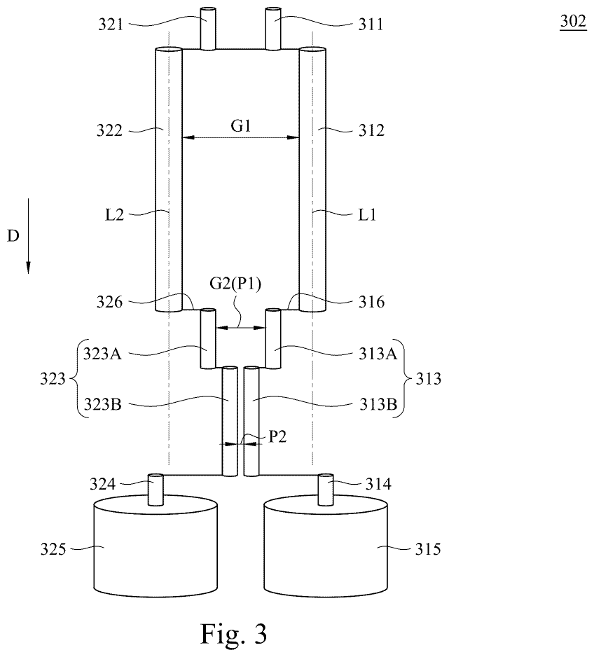

FIG. 3 is a side view of one of differential pair routings 302 according to one embodiment of the present disclosure. As shown in FIG. 3, the differential pair routings 302 of this embodiment is substantially the same as the differential pair routings 300 described above, except that the first laser through hole 313 and the second laser through hole 323 gradually approach towards each other along the direction D from the core layer 110 towards the second plate layers 130 of the multilayer board structure 100, rather than gradually apart from each other. However, the first laser through hole 313 and the second laser through hole 323 do not exceed out of a scope between the imaginary extension line L1 of the first conductive hole 312 and the imaginary extension line L2 of the second conductive hole 322. More specifically, a first via hole spacing P1 is defined between the first segment 313A and the third segment 323A, and a second via hole spacing P2 is defined between the second segment 313B and the fourth segment 323B. The first via hole spacing P1 is greater than the second via hole spacing P2, and is the same as the second spacing G2.

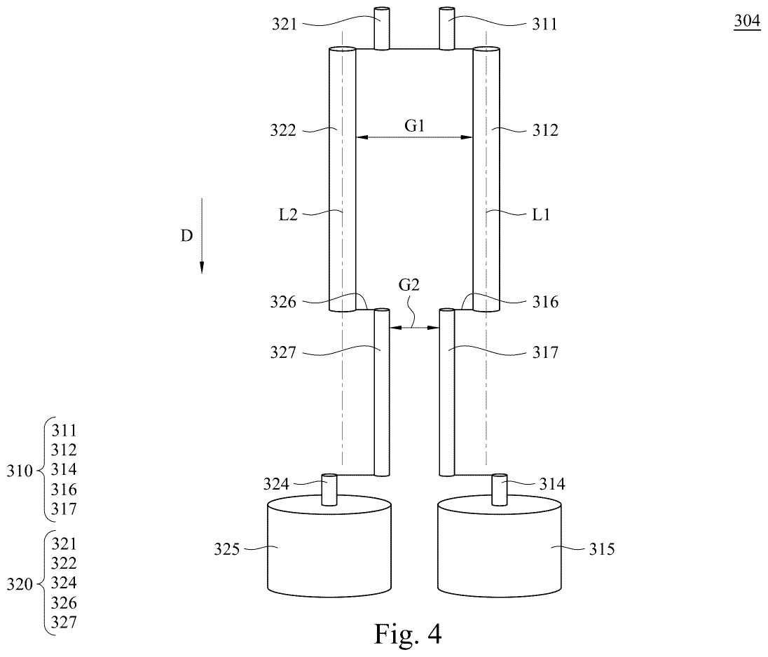

FIG. 4 is a side view of one of differential pair routings 304 according to one embodiment of the present disclosure. As shown in FIG. 4, the differential pair routings 304 of this embodiment is substantially the same as the differential pair routings 300 described above, except that the first laser through hole 317 and the second laser through hole 327 are parallel to each other, rather than gradually approach towards each other along the direction D from the core layer 110 towards the second plate layers 130 of the multilayer board structure 100. In other words, the patterns of the first laser through hole 317 and the second laser through hole 327 are not stepped but linear, and the first laser through hole 317 are parallel to the first conductive hole 312, and the second laser through hole 327 are parallel to the second conductive hole 322. More specifically, the minimum linear distance between the first laser through hole 317 and the second laser through hole 327 is the same as the second spacing G2.

In addition, as shown in FIG. 1 and FIG. 2, the spacing between adjacent laser through holes of two adjacent ones of the differential pair routings 300 is greater than the second spacing G2 described above, and can be more than 6 times the second spacing G2 according to design requirements.

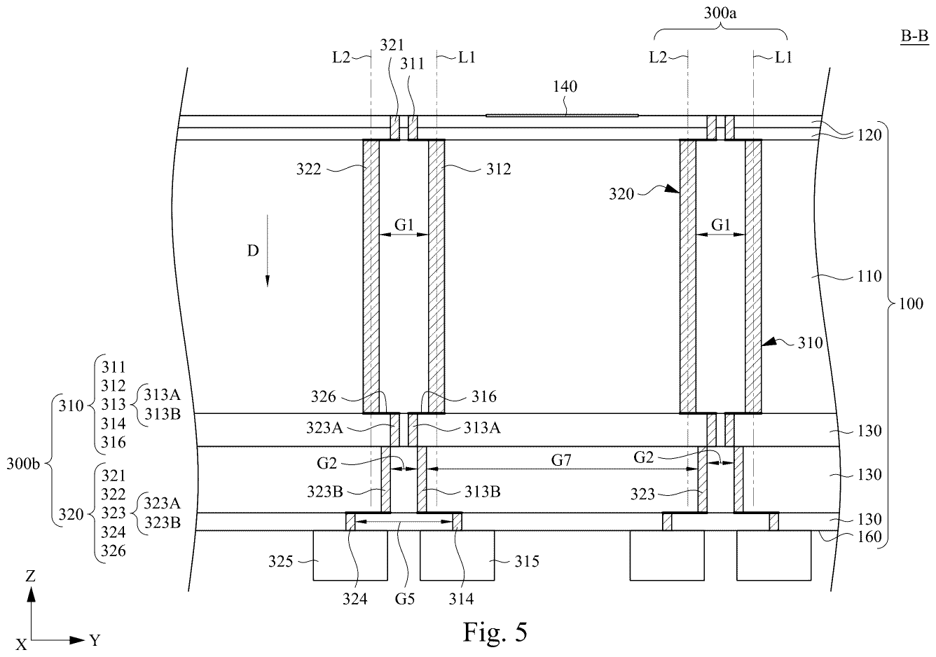

FIG. 5 is a cross-sectional view of the circuit board device 10 of FIG. 1 taken along a line B-B. More specifically, in any two adjacent ones of the differential pair routings 300a and 300b, a trace spacing G7 is defined between the second laser through hole 323 of one of the adjacent differential pair routings 300a and the first laser through hole 313 of the other of the adjacent differential pair routings 300b, and the trace spacing G7 is greater than the second spacing G2, and the trace spacing G7 is 6 to 30 times the second spacing G2, however, the disclosure is not limited thereto.

It is noted, the above-mentioned the differential pair routings 300a and 300b and the differential pair routings 300 have the same structure, as described above, and will not be described in detail.

In this way, the distance between two adjacent differential pair routings 300 (e.g., 300a, 300b) is increased by designing the pattern of the differential pair routings, thereby reducing the crosstalk generated when the signal is transmitted between the two adjacent differential pair routings 300, thereby improving the signal integrity.

Thus, through the construction of the embodiments above, even if the components on the circuit board device are gradually arranged closely in position, the circuit board device of the present disclosure can still reduce the crosstalk effect during signal transmission and improve signal integrity.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A circuit board device, comprising:
a multilayer board structure comprising a core layer, at least one first plate layer and a plurality of second plate layers stacked one another, and the core layer that is sandwiched between the at least one first plate layer and the second plate layers; and
a plurality of differential pair routings, each of the differential pair routings comprising:
a first plating through hole (first PTH) comprising a first conductive hole and a first laser through hole, the first conductive hole that is located within the core layer, and the first laser through hole that is sequentially passing through the second plate layers and electrically connected to the first conductive hole; and
a second plating through hole (second PTH) comprising a second conductive hole and a second laser through hole, the second conductive hole that is located within the core layer, and the second laser through hole that is sequentially passing through the second plate layers and electrically connected to the second conductive hole,
wherein when viewed in cross-sectional view:
a pattern of the first PTH and a pattern of the second PTH are mirror-symmetrical to each other, the second conductive hole is parallel to the first conductive hole, and a first spacing is formed between the second conductive hole and the first conductive hole, the first laser through hole and the second laser through hole are completely between an imaginary extension line of the first conductive hole and an imaginary extension line of the second conductive hole, and a second spacing defined between the first laser through hole and the second laser through hole is smaller than the first spacing.

2. The circuit board device of claim 1, wherein the first laser through hole and the second laser through hole are parallel to each other, or gradually approach or apart away from each other in a direction from the core layer towards the second plate layers of the multilayer board structure.

3. The circuit board device of claim 1, wherein a pattern of the first laser through hole and a pattern of the second laser through hole are both close to each other.

4. The circuit board device of claim 3, wherein the first laser through hole comprises a first segment and a second segment, the first segment is connected to the second segment and the first conductive hole, and the second laser through hole comprises a third segment and a fourth segment, the third segment is connected to the fourth segment and the second conductive hole, a first via hole spacing is defined between the first segment and the third segment, and a second via hole spacing is defined between the second segment and the fourth segment,
wherein the first via hole spacing is greater than the second via hole spacing, or the second via hole spacing is greater than the first via hole spacing.

5. The circuit board device of claim 1, wherein a pattern of the first laser through hole and a pattern of the second laser through hole are both linear, and the first conductive hole is parallel to the first laser through hole, and the second conductive hole is parallel to the second laser through hole.

6. The circuit board device of claim 1, wherein the first PTH further comprises a first solder-ball via within the second plate layers for connecting to a first solder ball; and
the second PTH further comprises a second solder-ball via within the second plate layers for connecting to a second solder ball,
wherein the first laser through hole is connected to the first conductive hole and the first solder-ball via, and the second laser through hole is connected to the second conductive hole and the second solder-ball via, and a first gap defined between the first solder-ball via and the second solder-ball via is greater than the first spacing.

7. The circuit board device of claim 1, wherein a configuration area is defined between the imaginary extension line of the first conductive hole and the imaginary extension line of the second conductive hole,
wherein the first PTH and the second PTH do not have any laser through hole outside the configuration area.

8. The circuit board device of claim 1, wherein a connection line between hole-axes of the first conductive hole and the second conductive hole has an extension direction, and the first laser through hole and the second laser through hole respectively extend along the extension direction.

9. The circuit board device of claim 1, wherein in two adjacent ones of the differential pair routings, a trace spacing is defined between the first laser through hole of one of the two adjacent ones of the differential pair routings and the second laser through hole of the other of the two adjacent ones of the differential pair routings, wherein the trace spacing is greater than the second spacing.

10. The circuit board device of claim 9, wherein the trace spacing is 6 to 30 times the second spacing.

11. The circuit board device of claim 1, wherein a pattern of the first laser through hole and a pattern of the second laser through hole are both stepped and symmetrically arranged.

12. The circuit board device of claim 1, wherein the multilayer board structure further comprises a ground layer and a plurality of closed openings spaced formed on the ground layer, and each of the closed openings surrounds and exposes a corresponding one of the differential pair routings.

13. A circuit board device, comprising:
a multilayer board structure comprising a solder-ball surface, a core layer and a plurality of plate layers stacked one another, and the plate layers sandwiched between the solder-ball surface and the core layer; and
a plurality of differential pair routings spaced distributed within the multilayer board structure, each of the differential pair routings comprising a P-type PTH and a N-type PTH which are mirror-symmetrical, the P-type PTH comprising a first conductive hole and a first laser through hole, the first conductive hole that is located within the core layer, and the first laser through hole that is sequentially passing through the plate layers and electrically connected to the first conductive hole, and the N-type PTH comprising a second conductive hole and a second laser through hole, the second conductive hole that is located within the core layer, and the second laser through hole that is sequentially passing through the plate layers and electrically connected to the second conductive hole,
wherein when viewed in cross-sectional view:
the second conductive hole is parallel to the first conductive hole, and a first spacing is formed between the second conductive hole and the first conductive hole, the first laser through hole and the second laser through hole are completely between an imaginary extension line of the first conductive hole and an imaginary extension line of the second conductive hole, and a second spacing defined between the first laser through hole and the second laser through hole is smaller than the first spacing.

14. The circuit board device of claim 13, wherein the first laser through hole and the second laser through hole are parallel to each other, or gradually approach or apart away from each other in a direction from the core layer towards the plate layers of the multilayer board structure.

15. The circuit board device of claim 13, wherein a pattern of the first laser through hole and a pattern of the second laser through hole are both close to each other.

16. The circuit board device of claim 15, wherein the first laser through hole comprises a first segment and a second segment, the first segment is connected to the second segment and the first conductive hole, and the second laser through hole comprises a third segment and a fourth segment, the third segment is connected to the fourth segment and the second conductive hole, a first via hole spacing is defined between the first segment and the third segment, and a second via hole spacing is defined between the second segment and the fourth segment,
wherein the first via hole spacing is greater than the second via hole spacing, or the second via hole spacing is greater than the first via hole spacing.

17. The circuit board device of claim 13, wherein a pattern of the first laser through hole and a pattern of the second laser through hole are both linear, and the first conductive hole is parallel to the first laser through hole, and the second conductive hole is parallel to the second laser through hole.

18. The circuit board device of claim 13, wherein the P-type PTH further comprises a first solder-ball via within the plate layers for connecting to a first solder ball; and
the N-type PTH further comprises a second solder-ball via within the plate layers for connecting to a second solder ball,
wherein the first laser through hole is connected to the first conductive hole and the first solder-ball via, and the second laser through hole is connected to the second conductive hole and the second solder-ball via, and a first gap defined between the first solder-ball via and the second solder-ball via is greater than the first spacing.

19. The circuit board device of claim 13, wherein a configuration area is defined between the imaginary extension line of the first conductive hole and the imaginary extension line of the second conductive hole,
wherein the P-type PTH and the N-type PTH do not have any laser through hole outside the configuration area.

20. The circuit board device of claim 13, wherein in any two adjacent ones of the differential pair routings, a trace spacing is defined between the first laser through hole of one of the adjacent differential pair routings and the second laser through hole of the other of the adjacent differential pair routings,
wherein the trace spacing is 6 to 30 times the second spacing.
